(19) United States
(12) Patent Application Publication
(10) Pub. No.: US 2003/0070128 A1
(43) Pub. Date: Apr. 10, 2003

(54) Scan path circuit for test of logic circuit

(75) Inventors: Nobuhiko Akasaka, Kawasaki (JP); Tohru Koike, Komae (JP)

Correspondence Address: ARENT FOX KINTNER PLOTKIN & KAHN, PLLC, Suite 600, 1050 Connecticut Avenue, N.W., Washington, DC, 20036-5339, US

(73) Assignee: Fujitsu Limited

(21) Appl. No.: 10/198,957

(22) Filed: Jul. 22, 2002

(30) Foreign Application Priority Data
Oct. 9, 2001 (JP) 2001-310995

(51) Int. Cl. G01R 31/28; H03K 19/0175

(52) U.S. Cl. 714/726; 326/62

(57) ABSTRACT

Disclosed is a scan path circuit for testing a logic circuit, which comprises a plurality of scan cells each having a scan in SI, a cell output and a clock input for receiving a clock signal, connected in series with respect to the scan ins and cell outputs. Each scan cell includes a scan flip-flop 21, and a selection circuit 31 which selects either a signal of a scan in SI or a signal of a scan out SO of the scan flip-flop 21 according on a selection controlling signal to provide the selected signal to the cell output. Determining the values of the selector controlling signal with a bypass controlling shift resister 45 permits forming a bypass between the scan data input terminal SDI and the scan in SI of any scan flip-flop except the first stage flip-flop, and/or a bypass between the scan data output terminal SDO and the scan out SO of any scan flip-flop except the final stage scan flip-flop.

### BACKGROUND OF THE INVENTION

1. Field of the Invention

The present invention relates to a scan path circuit provided to a logic circuit for achieving an easy function test, and an integrated circuit device having the same.

2. Description of the Related Art

The circuit scale has been increased to obtain higher density and efficiency of an integrated circuit device, thereby enlarging the number of test patterns for detecting the defect thereof. In order to obtain a higher defect detecting ratio with a smaller number of test patterns, there is provided with a scan register that employs as scan chains the scan flip-flops 21 to 24 formed by replacing D flip-flops, as shown in FIG. 10. In case of performing a function test of a combinational circuit 11, the following operations are carried out.

(1) After forming a scan path by setting a scan mode input terminal SMD high for enabling a scan mode of the scan flip-flops 21 to 24, a test pattern is transferred in serial fashion from a scan data input terminal SDI to the scan register.

(2) After allowing the scan flip-flops 21 to 24 to operate as usual D flip-flops by setting the scan mode input terminal SMD low to enable a usual mode of the scan flip-flops 21 to 24, an inner output of the combinational circuit 11 is latched in part or all of the flip-flops 21 to 24.

(3) After setting a scan mode input terminal SMD high for enabling a scan mode of the scan flip-flops 21 to 24, a test result data maintained in the scan register is transferred in serial fashion and externally output from a scan data output terminal SDO, and the output test result data is compared with an expected pattern value.

FIG. 11 is a time chart showing a case of performing a function test of a circuit 12, which is part of the combinational circuit 11, using the scan path. In this figure, “21.SO” denotes a signal of a scan out SO of the scan flip-flop 21, and “22.SO” to “24.SO” denote signals of the corresponding scan outs SO.

In the beginning 4 clock cycles C1 to C4, the scan mode input terminal SMD is set high to form a scan path, and the scan data input terminal SDI is provided with ‘0100’ in serial fashion. On rising edge of clock cycle C4, ‘0100’ is latched in the scan flip-flops 24 to 21.

In the next clock cycle C5, the scan mode input terminal SMD is set low, and the output of the circuit 12 is latched in the scan flip-flop 22 on its rising edge.

In the next clock cycles C6 and C7, the scan mode input terminal SMD is set high to form the scan path, and ‘1’ latched in the scan flip-flop 22 is shifted in the scan register to be output from the scan data output terminal SDO in the clock cycle C7.

However, there is also a case where the scan register is composed of thousands of scan flip-flops in fact for a large scaled integrated circuit device. Thus, the number of clock cycles for serial transferring in the above operations (1) and (2) is very large. A serial transferring must be carried out each for the great number of test patterns, increasing the test time.

### SUMMARY OF THE INVENTION

Accordingly, an object of the present invention is to provide a scan path circuit for testing a logic circuit, which can shorten the test time.

In one aspect of the present invention, there is provided with a scan path circuit for testing a logic circuit, comprising: a scan register including a plurality of scan flip-flops, each scan flip-flop having a scan in, a scan out and a clock input, the scan flip-flops being connected in series with respect to the respective scan ins and scan outs; and a selection circuit for selecting, based on a selection controlling signal, either a signal of a scan out of a final stage scan flip-flop of the scan register or a signal of a scan out of at least one of the other scan flip-flops of the scan register.

According to this configuration, because the test result data is bypassed and outputted by the selection circuit, the serial transferring time of the test result data is shortened or zero, thereby decreasing the test time.

In another aspect of the present invention, there is provided with a scan path circuit for testing a logic circuit, comprising: first and second scan registers, each scan register including a plurality of scan flip-flops, each scan flip-flop having a scan in, a scan out and a clock input, the scan flip-flops of each scan register being connected in series with respect to the respective scan ins and scan outs; and a selection circuit which selects, according to a selection controlling signal, either a signal of a scan in of a first stage scan flip-flop of the first scan register or a signal of a scan out of a final stage scan flip-flop of the first scan register, and provides the selected signal to a scan in of a first stage scan flip-flop of the second scan register.

According to this configuration, because the test pattern is bypassed by the selection circuit and is provided to the scan in of the intermediate scan flip-flop of the scan register (a first stage scan flip-flop of the second scan register), the serial transferring time of the test pattern is shortened or zero, thereby decreasing the test time. Further, the bypassing permits data having no concern with the test to be omitted from the test pattern, in result of decreasing the data amount of the test pattern.

In still another aspect of the present invention, there is provided with a scan path circuit for testing a logic circuit, comprising: a plurality of scan cells, each scan cell having a cell output, each scan cell including: a scan flip-flop having a scan in, a scan out and a clock input; and a selection circuit which selects, based on a selection controlling signal, either a signal of the scan in or a signal of the scan out of the scan flip-flop, and provides the selected signal to the cell output; wherein the plurality of scan flip-flops being connected in series with respect to the respective scan ins and scan outs.

According to this configuration, determining the value of the selection controlling signal makes it possible to form a bypass between the scan in of the first stage scan flip-flop and the scan in of any of the other scan flip-flops, and/or a bypass between the scan out of the final stage scan flip-flop and the scan out of any of the other scan flip-flops.

### BRIEF DESCRIPTION OF THE DRAWINGS

FIG. 1 is a schematic block diagram showing an integrated circuit device provided with a scan path circuit according to a first embodiment of the present invention.

FIG. 2 is a time chart in case of performing a function test of the circuit 12 shown FIG. 1.

FIG. 3 is a schematic block diagram showing an integrated circuit device provided with a scan path circuit according to a second embodiment of the present invention.

FIG. 4 is a time chart in case of performing a function test of the circuit 12 shown FIG. 3.

FIG. 5 is a schematic block diagram of an integrated circuit device provided with scan path circuit according to a third embodiment of the present invention.

FIG. 6 is a view for illustrating the circuit operation of FIG. 5, wherein a bypass is formed by a value of bypass controlling data, as shown by bold line.

FIG. 7 is a view for illustrating the circuit operation of FIG. 5, wherein another bypass is formed by another value of bypass controlling data, as shown by bold line.

FIG. 8 is a schematic block diagram of an integrated circuit device provided with a scan path circuit according to a fourth embodiment of the present invention.

FIG. 9 is a schematic block diagram of an integrated circuit device provided with a scan path circuit according to a fifth embodiment of the present invention.

FIG. 10 is a schematic block diagram showing an integrated circuit device provided with the conventional scan path circuit for an easy function test.

FIG. 11 is a time chart showing a case of performing a function test of a circuit 12 of FIG. 10.

### DESCRIPTION OF THE PREFERRED EMBODIMENTS

The present invention will hereinafter be described in more detail with reference to the drawings.

First Embodiment

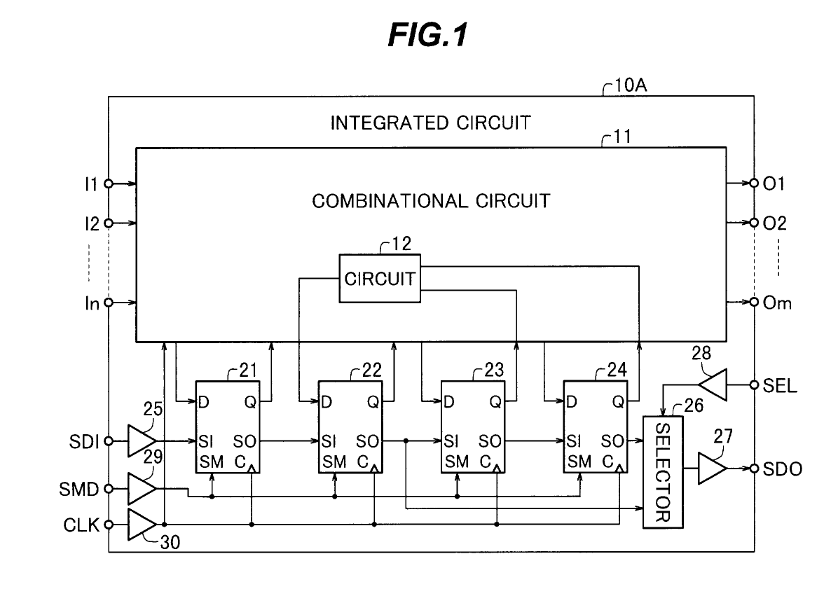

FIG. 1 is a schematic block diagram showing an integrated circuit device 10A provided with a scan path circuit according to the first embodiment of the present invention.

The integrated circuit device 10A comprises a combinational circuit 11, and the other circuit which is a scan path circuit. FIG. 1 shows a case where the scan path circuit is composed of four scan flip-flops for simplification. D flip-flops usually employed in the integrated circuit device 10A have been replaced with the respective scan flip-flops 21 to 24.

The scan flip-flop 21 has a data input D, a data output Q and a clock input C as a usual D flip-flop, and additionally has a scan in SI, a scan out SO and a scan mode input SM. The same signal is outputted from both the data output Q and the scan out SO. On the rising edge of the clock input C, the scan flip-flop 21 selects and latches the logic value of the data input D in normal mode where the scan in mode input SM is low, and on the other hand, it selects and latches the logic value of the scan in SI in scan mode where the scan mode input SM is high. In both modes, the latched logic value is outputted from the data output Q and the scan output terminal SO.

The data inputs D and the data outputs Q of the scan flip-flops 21 to 24 are connected to the combinational circuit 11. The combinational circuit 11 receives signals from the external through signal input terminals I1 to In and outputs signals to the external through signal output terminals O1 to Om. The combinational circuit 11 may include buffer gates connected between at least one of the signal input terminals I1 to In and data inputs D of at least one of the scan flip-flops 21 to 24, and/or buffer gates connected between the data outputs Q of at least one of the scan flip-flops 21 to 24 and at least one of the signal output terminals O1 to Om. FIG. 1 shows a case where the data outputs Q of both the scan flip-flops 23 and 24 are connected to part of the circuit 12, and the output of the circuit 12 is provided to the data input D of the scan flip-flop 22.

In order to form the scan register, the scan in SI and the scan out SO of each scan flip-flops 21 to 24 are connected each other in series. A scan data (text pattern) is provided to the scan in SI of the scan flip-flop 21 from the external through the input terminal SDI and the buffer gate 25.

The scan outs SO of the scan flip-flops 24 and 22 are connected to first and second inputs of a selector 26, respectively. The output of the selector 26 is connected to the data output terminal SDO through a buffer gate 27, while the selection controlling input thereof is connected to the a selection controlling signal input terminal SEL through a buffer gate 28. The selector 26 selects the scan out SO (referred to as “24.SO” hereinafter) of the scan flip-flop 24 when the terminal SEL is low, while selects and bypasses “22.SO” when the terminal SEL is high. The scan data (test result data) is externally output through the scan data output terminal SDO to be compared with the expected pattern value of a test device not shown.

The scan mode signal is provided to the scan mode inputs SM of the scan flip-flops 21 to 24 from the external through the input terminal SMD and the buffer gate 29, and the scan register is brought into scan mode and normal mode, respectively, when the scan mode inputs SM of the scan flip-flops 21 to 24 are high and low. The clock input is provided to the clock inputs C of the scan flip-flops 21 to 24 and the combinational circuit 11 from the external through the input terminal CLK and the buffer gate 30.

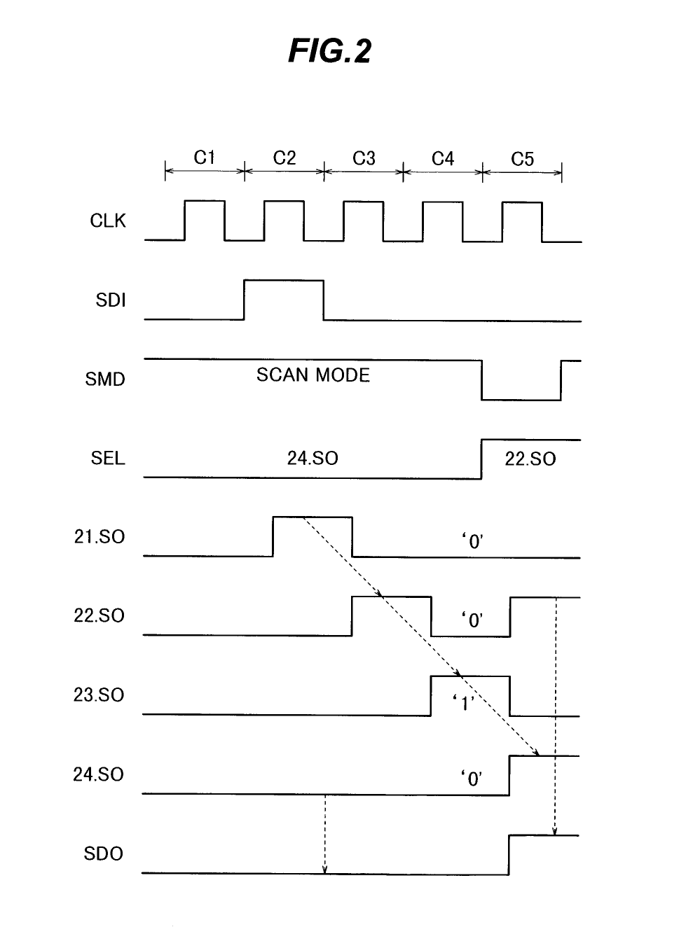

FIG. 2 is a time chart in case of performing a function test of the circuit 12 using the scan path circuit. The circuit 12 outputs “1” if it is normal when the data outputs Q of the scan flip-flops 23 and 24 are ‘1’ and ‘0’, respectively.

(1) In the beginning clock cycles C1 to C4, the scan mode input terminal SMD is set high to bring the scan flip-flops 21 to 24 into scan mode, thereby forming a scan path. In this state, the scan data input terminal SDI is provided with ‘0100’ in serial fashion, and on the rising edge of the clock cycle C4, the 4 bit register of the scan flip-flops 24 to 21 latches ‘0100’.

(2) In the clock cycle C5, the scan mode input terminal SMD is set low to bring the scan flip-flops 21 to 24 into normal mode, whereby the scan path is disappeared and the scan flip-flops 21 to 24 serve as usual D flip-flops. On its rising edge, the output of the circuit 12 is latched in the scan flip-flop 22. In the clock cycle C5, the selection controlling signal input terminal SEL is set high, thereby outputting ‘22.SO’ through the scan data output terminal SDO.

According to this first embodiment, because the test result data is bypassed and outputted by the selector 26, the serial transferring time of the test result data is shortened or zero as the above-mentioned case, thereby decreasing the test time.

In addition, the selection controlling signal input terminal SEL may be set high before the clock cycle C5. Further, the selector 26 may select, based on the controlling signal, one of the scan outs of the plurality of the scan flip-flops, including the scan out SO of the final stage scan flip-flop 24 of the scan path.

Second Embodiment

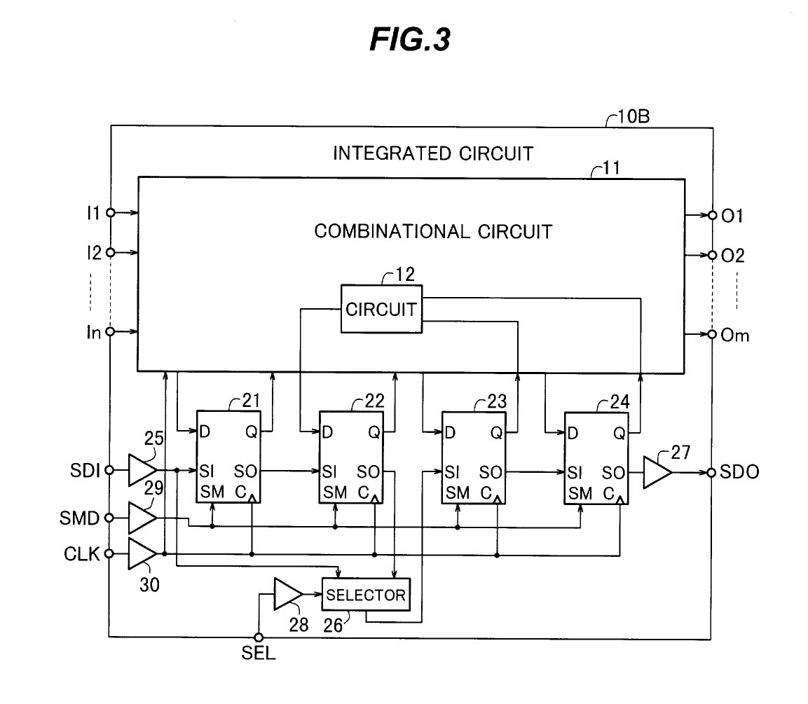

FIG. 3 is a schematic block diagram showing an integrated circuit device 10B provided with a scan path circuit according to the second embodiment of the present invention.

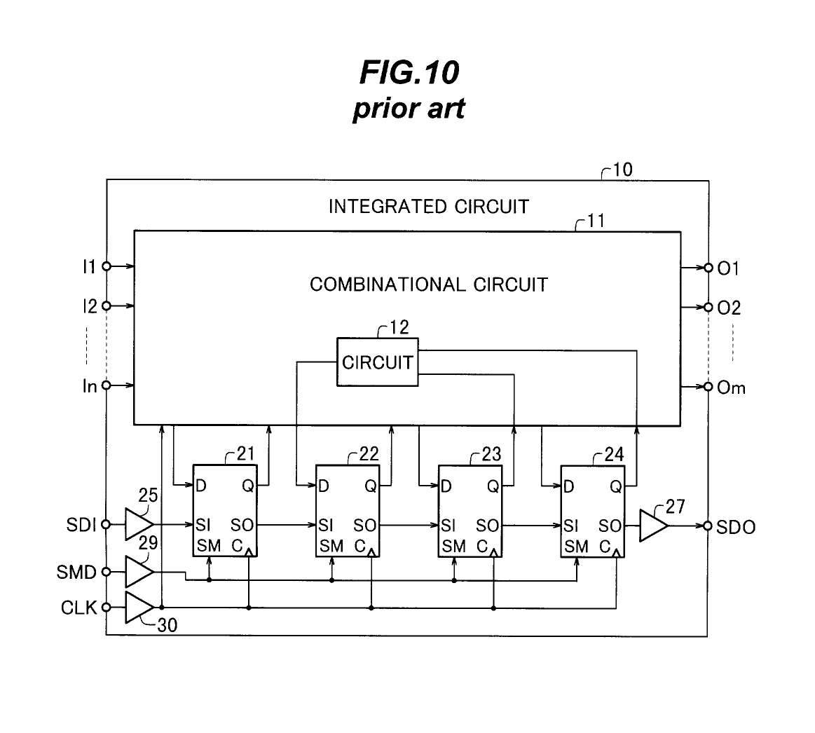

First and second inputs of a selector 26 are connected, respectively, to the scan in SI of the scan flip-flop 21 and the scan out SO of the scan flip-flop 22, its output is connected to the scan in SI of the next scan flip-flop 23, and its controlling input is connected to the selection controlling signal input terminal SEL through the buffer gate 28. The other components of the integrated circuit device 10B have the same structures as those shown in FIG. 10.

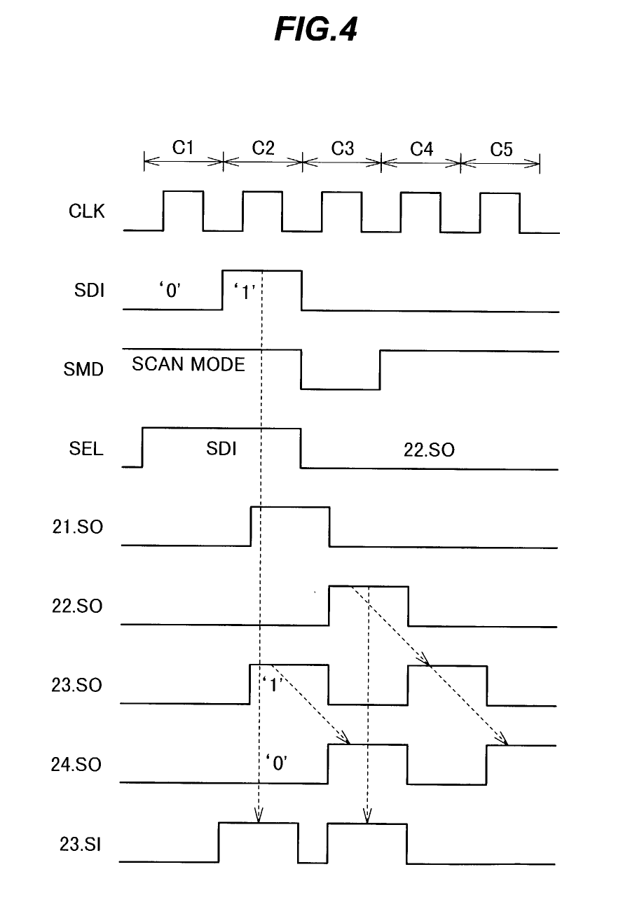

FIG. 4 is a time chart in case of performing a function test of the circuit 12 using this scan path circuit.

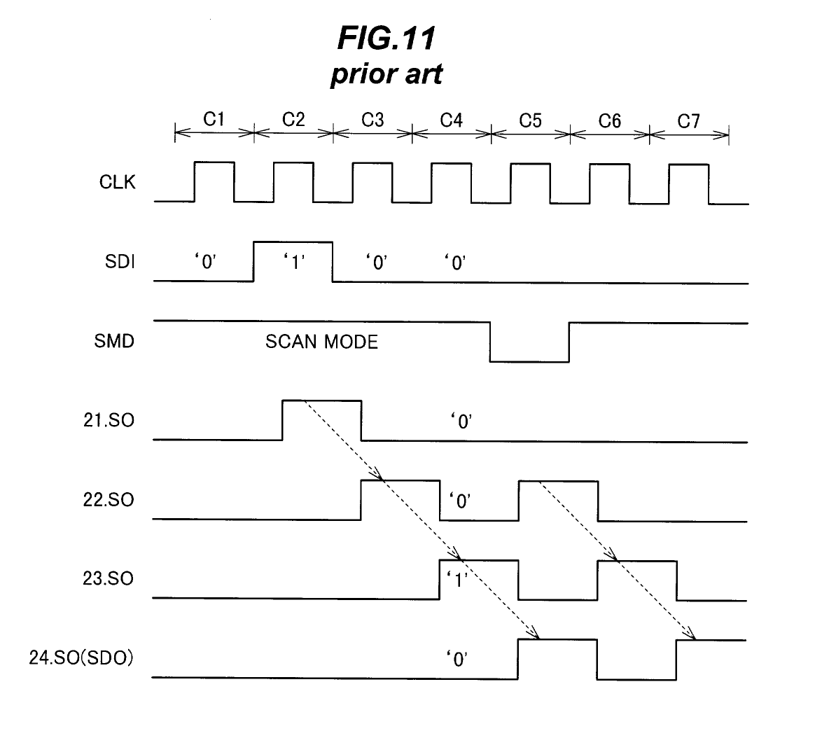

(1) In the beginning two clock cycles C1 to C2, the scan mode input terminal SMD and the selection controlling signal input terminal SEL are set high to bring the scan flip-flops 21 to 24 into scan mode, and to enable the selector 26 to form a bypass between the scan data input terminal SDI and 23.SI. In this state, the scan data input terminal SDI is provided with ‘01’ in serial fashion, and the register composed of the scan flip-flops 24 and 23 latches ‘01’ for a test on the rising edge of the clock cycle C2. This allows shortening the test data transferring time by 2 clock cycles than the case of FIG. 11.

(2) In the clock cycle C3, the scan mode input terminal SMD is set low to bring the scan flip-flops 21 to 24 into normal mode, and on its rising edge, the output of the circuit 12 is latched in the scan flip-flop 22 as a test result.

(3) The scan mode input terminal SMD is set high to bring the scan flip-flops 21 to 24 into scan mode, and then the test result maintained in the scan flip-flop 22 is transferred in serial fashion in the scan register and is outputted through the scan data output terminal SDO in the clock cycle C5.

According to this second embodiment, because the test pattern is bypassed by the selector 26 and is provided to the scan in of the intermediate scan flip-flop of the scan register, the serial transferring time of the test pattern is shortened or zero, thereby decreasing the test time. Further, the bypassing permits data having no concern with the test to be omitted from the test pattern, in result of decreasing the data amount of the test pattern.

Third Embodiment

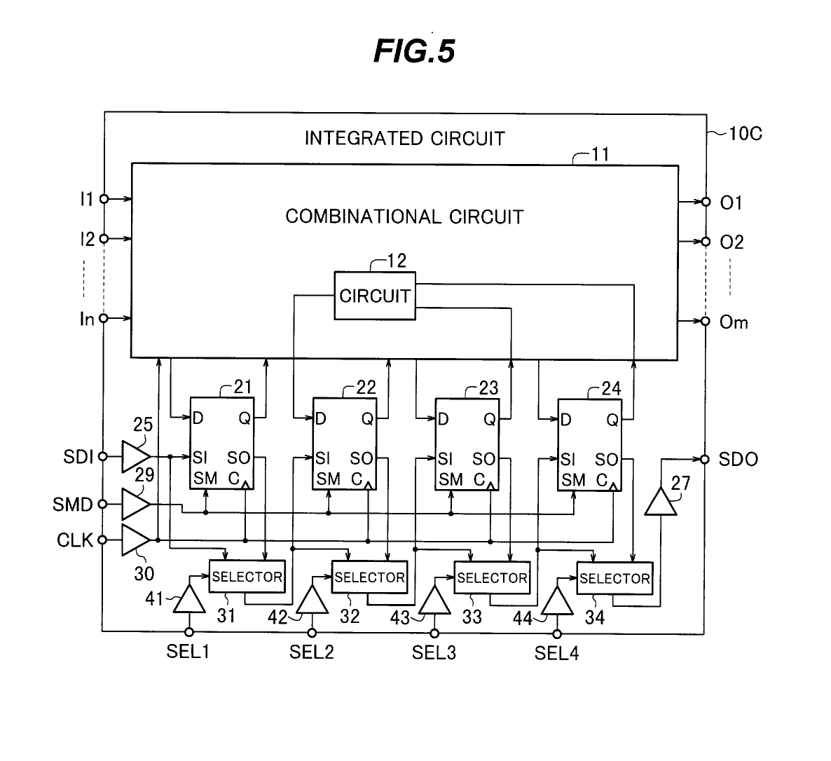

FIG. 5 is a schematic block diagram of an integrated circuit device 10C, which is provided with a scan path circuit according to the third embodiment of the present invention.

This integrated circuit device 10C is provided with selectors 31 to 34, respectively, for the scan flip-flops 21 to 24, and buffer gates 41 to 44 and selection controlling signal input terminals SEL1 to SEL4, respectively, for the selectors 31 to 34. First and second inputs of the selector 31 are connected, respectively, to a scan in SI of the scan flip-flop 21 and the scan out SO, its output is connected to the scan in SI of the next scan flip-flop 22, and its controlling input is connected to the terminal SEL1 through the buffer gate 41. Each of the selectors 32 to 34 has a similar connection structure, except the output of the selector 34 is connected to the scan data output terminal SDO through the buffer gate 27.

According to the third embodiment, determining the input values of the selection controlling signal terminals SEL1 to SEL4 makes it possible to form a bypass between the scan data input terminal SDI and the scan in SI of any scan flip-flop, and/or a bypass between the scan data output terminal SDO and the scan out of any scan flip-flop. This allows the serial transferring time of the test pattern and/or test result data to be shortened or zero. Further, the bypassing permits data having no concern with the test to be omitted from the test pattern, in result of decreasing the data amount of the test pattern.

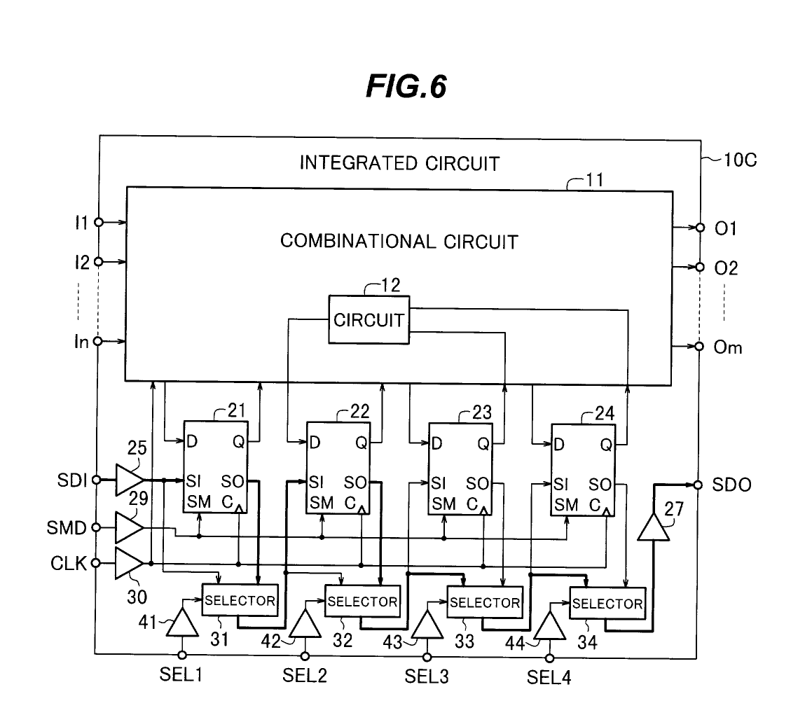

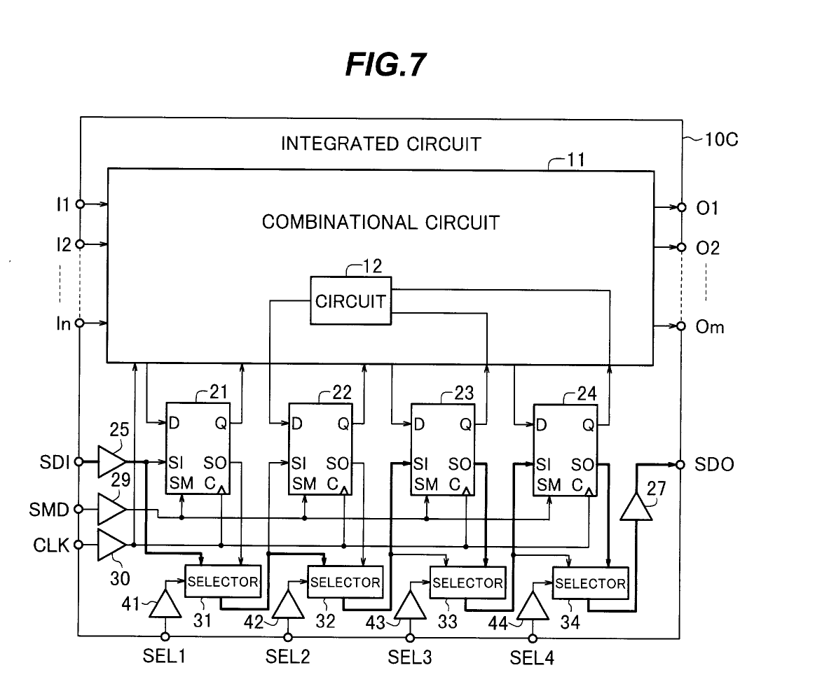

For example, when the selection controlling terminals SEL1 to SEL4 are provided with ‘0011’ as a bypass controlling data, a bypass is formed as shown by bold line in FIG. 6, which is the same as a bypass formed when SEL is given as ‘1’ in the structure of FIG. 1. In addition, in case where the selection controlling terminals SEL1 to SEL4 are provided with ‘1100’ as a bypass controlling data, a bypass is formed as shown by bold line in FIG. 7, which is the same as a bypass formed when SEL is given as ‘1’ in the structure of FIG. 3.

Fourth Embodiment

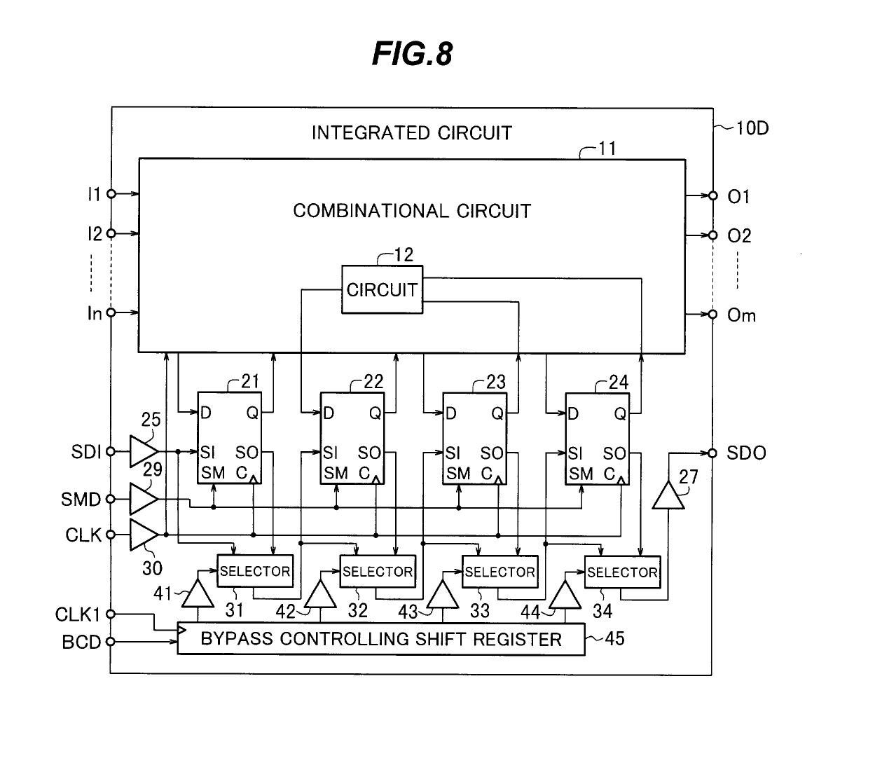

FIG. 8 is a schematic block diagram of an integrated circuit device 10D provided with a scan path circuit according to the fourth embodiment of the present invention.

A large number of scan flip-flops lead to insufficient space to form the external terminals of the selection controlling signals. Thus, this integrated circuit device 10D employs a bypass controlling shift register 45 and a bypass controlling data input terminal BCD, where a bypass controlling data is transferred in serial fashion to the bypass controlling shift register 45 from the external through the bypass controlling data input terminal BCD. The shift register 45 is a 4 bit register and has 4 bit outputs, which are supplied to the buffer gates 41 to 44. A shift clock input and a serial data input of the shift register 45 are connected, respectively, to the clock input terminal CLK1 and the bypass controlling data input terminal BCD of this integrated circuit device 10D.

The other components of the integrated circuit device 10D have the same structures as those shown in FIG. 5.

Fifth Embodiment

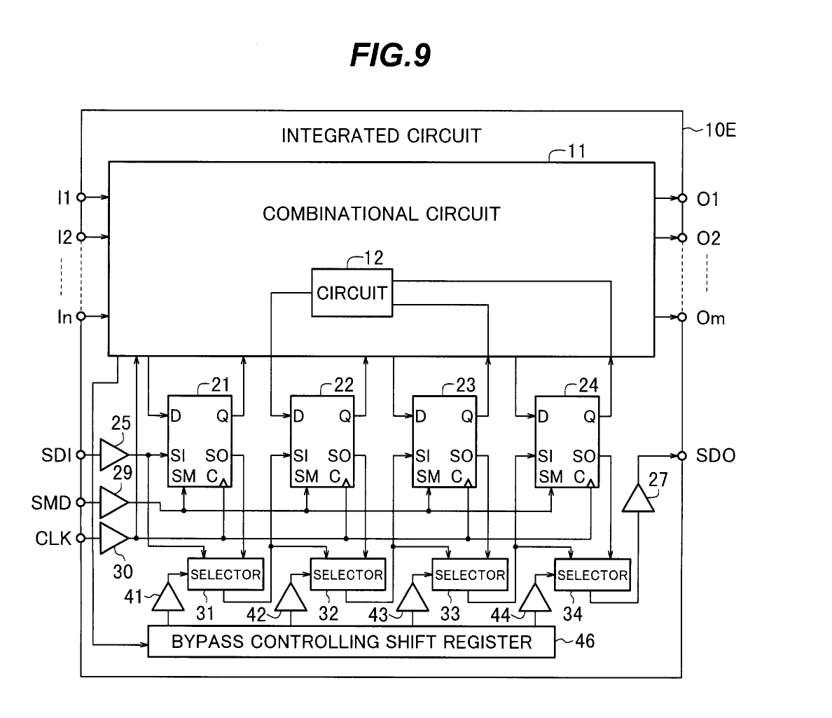

FIG. 9 is a schematic block diagram of an integrated circuit device 10E provided with a scan path circuit according to the fifth embodiment of the present invention.

Instead of the bypass controlling shift resister 45 of FIG. 8, this integrated circuit device 10E includes a bypass controlling register 46, which receives a bypass controlling data in parallel fashion. For instance, 4 bit nodes among the signal input terminals I1 to In are connected to the 4 bit inputs of the bypass controlling register 46 through buffer circuits not shown which are provided in the integrated circuit 11A. The integrated circuit device 10E may include a CPU therein, and perform data setting of the bypass controlling register 46 through the bus of the CPU.

The forgoing embodiments are merely exemplary and are not to be construed as limiting the present invention. The present teachings can be readily applied to other types of apparatuses or methods. The description of the present invention is intended to be illustrative, and not to limit the scope of the claims. Many alternatives, modifications, and variations will be apparent to those skilled in the art.

What is claimed is:

1. A scan path circuit for testing a logic circuit, comprising:
a scan register including a plurality of scan flip-flops, each scan flip-flop having a scan in, a scan out and a clock input, the scan flip-flops being connected in series with respect to the respective scan ins and scan outs; and
a selection circuit for selecting, based on a selection controlling signal, either a signal of a scan out of a final stage scan flip-flop of the scan register or a signal of a scan out of at least one of the other scan flip-flops of the scan register.

2. An integrated circuit device comprising:
a scan path circuit for testing a logic circuit, including:
a scan register including a plurality of scan flip-flops, each scan flip-flop having a scan in, a scan out, a clock input, a data input and a data output, the scan flip-flops being connected in series with respect to the respective scan ins and scan outs; and
a selection circuit for selecting, based on a selection controlling signal, either a signal of a scan out of a final stage scan flip-flop of the scan register or a signal of a scan out of at least one of the other scan flip-flops of the scan register;
a combinational circuit connected to the data inputs and data outputs of the plurality of scan flip-flops of the scan path circuit;
an external scan data input terminal which receives a serial test data and is connected to a scan in of a first stage scan flip-flop of the plurality of scan flip-flops; and
an external scan data output terminal which outputs a serial test result data and is connected to an output of the selection circuit of the scan path circuit.

3. A scan path circuit for testing a logic circuit, comprising:
first and second scan registers, each scan register including a plurality of scan flip-flops, each scan flip-flop having a scan in, a scan out and a clock input, the scan flip-flops of each scan register being connected in series with respect to the respective scan ins and scan outs; and
a selection circuit which selects, according to a selection controlling signal, either a signal of a scan in of a first stage scan flip-flop of the first scan register or a signal of a scan out of a final stage scan flip-flop of the first scan register, and provides the selected signal to a scan in of a first stage scan flip-flop of the second scan register.

4. An integrated circuit device comprising:
a scan path circuit for testing a logic circuit, including:
first and second scan registers, each scan register including a plurality of scan flip-flops, each scan flip-flop having a scan in, a scan out, a clock input, a data input and a data output, the scan flip-flops of each scan register being connected in series with respect to the respective scan ins and scan outs; and
a selection circuit which selects, according to a selection controlling signal, either a signal of a scan in of a first stage scan flip-flop of the first scan register or a signal of a scan out of a final stage scan flip-flop of the first scan register, and provides the selected signal to a scan in of a first stage scan flip-flop of the second scan register;
a combinational circuit connected to the data inputs and the data outputs of the plurality of scan flip-flops of the first and second scan register;
an external scan data input terminal which receives a serial test data and is connected to a scan in of a first stage scan flip-flop of the plurality of scan flip-flops of the first scan register; and
an external scan data output terminal which outputs a serial test result data and is connected to a scan out of a final stage scan flip-flop of the plurality of scan flip-flops of the second scan register.

5. A scan path circuit for testing a logic circuit, comprising: a plurality of scan cells, each scan cell having a cell output, each scan cell including:
a scan flip-flop having a scan in, a scan out and a clock input; and
a selection circuit which selects, based on a selection controlling signal, either a signal of the scan in or signal of the scan out of the scan flip-flop, and provides the selected signal to the cell output;
wherein the plurality of scan flip-flops being connected in series with respect to the respective scan ins and scan outs.

6. The scan path circuit according to claim 5, further comprising a bypass controlling register having a plurality of bits provided to the selection circuits of the plurality of scan cells as respective selection controlling signals.

7. The scan path circuit according to claim 6, wherein the bypass controlling register is a shift register.

8. An integrated circuit device comprising:
a scan path circuit for testing a logic circuit, comprising: a plurality of scan cells, each scan cell having a cell output, each scan cell including:
a scan flip-flop having a scan in, a scan out, a clock input, a data input and a data output; and
a selection circuit which selects, based on a selection controlling signal, either a signal of the scan in or a signal of the scan out of the scan flip-flop, and provides the selected signal to the cell output;
wherein the plurality of scan flip-flops being connected in series with respect to the respective scan ins and scan outs;
wherein the scan path circuit further comprising a bypass controlling register having a plurality of bits provided to the selection circuits of the plurality of scan cells as respective selection controlling signals;
a combinational circuit connected to the data inputs and the data outputs of the scan flip-flops of the plurality of scan cells;
an external scan data input terminal which receives a serial test data and is connected to a scan in of a first stage scan cell of the plurality of scan cells; and
an external scan data output terminal which outputs a serial test result data and is connected to a cell output of a final stage scan cell of the plurality of scan cells.

9. The integrated circuit device according to claim 8, wherein the bypass controlling register is a shift register having a shift in, the integrated circuit device further comprises:
an external controlling data input terminal which receives a bypass controlling serial data and is connected to the shift in of the shift register.
